(19) United States
(12) Patent Application Publication
(10) Pub. No.: US 2009/0078303 A1
(43) Pub. Date: Mar. 26, 2009

(54) Encapsulated Photovoltaic Device Used With A Reflector And A Method of Use for the Same

(75) Inventors: Thomas Brezoczky, Los Gatos, CA (US); Benyamin Buller, Sylania, OH (US); Chris M. Gronet, Portola Valley, CA (US)

Correspondence Address: JONES DAY, 222 EAST 41ST ST, NEW YORK, NY, 10017, US

(73) Assignee: Solyndra, Inc., Fremont, CA (US)

(21) Appl. No.: 12/235,496

(22) Filed: Sep. 22, 2008

Related U.S. Application Data
(60) Provisional application No. 60/974,711, filed on Sep. 24, 2007.

(51) Int. Cl. H01L 31/042

(52) U.S. Cl. 136/246

(57) ABSTRACT

An apparatus is provided that has photovoltaic modules and a concentrator mechanically attached to a frame. Each module has (i) an outer shell defining an inner volume, (ii) a substrate in the inner volume, and (iii) a material on the substrate that converts light to electric energy. The outer shell allows light energy that strikes the shell to be directed towards the material. The concentrator has concentrator assemblies, each associated with a respective photovoltaic module. Each concentrator assembly comprises a first and second surface that form a concave structure that transmits light energy entering the concave structure to the associated photovoltaic module. The first and second surfaces each comprise substantially the shape of the involute of the particular photovoltaic module associated with the concentrator assembly. Each photovoltaic module extends from a first to a second support of the frame and is electrically coupled to an electric contact in the first support.

### CROSS REFERENCE TO RELATED APPLICATION

This application claims priority to U.S. Patent Application No. 60/974,711, filed Sep. 24, 2007, which is hereby incorporated by reference herein in its entirety.

### FIELD

This application is directed to photovoltaic solar cell apparatus construction. In particular, it is directed to a photovoltaic cell or module and an associated reflector assembly.

### BACKGROUND

FIG. 1 is a schematic block diagram of a conventional photovoltaic device. A photovoltaic module 10 can typically have one or more photovoltaic cells 12a-b disposed within it. A photovoltaic cell conventionally is made by having a semiconductor junction 14 disposed between a layer of conducting material 18 and a layer of transparent conducting material 16. Light impinges upon the photovoltaic module 10 and transits through the transparent conducting material layer 16. Within the semiconductor junction 14, the photons interact with the material to produce electron-hole pairs. The semiconductor(s) typically is/are doped thereby creating an electric field extending from the semiconductor junction 14. Accordingly, when the holes and/or electrons created by the sunlight in the semiconductor, they will migrate depending on the polarity of the device either to the transparent conducting material layer 16 or the conducting material layer 18. This migration creates current within the cell which is routed out of the cell for storage and/or concurrent use.

One conducting node of the solar cell 12a is shown electrically coupled to an opposite node of another solar cell 12b. In this manner, the current created in one cell may be transmitted to another, where it is eventually collected. The currently depicted apparatus in FIG. 1 is shown where the solar cells are coupled in series, thus creating a higher voltage device. In another manner, (not shown) the solar cells can be coupled in parallel which increases the resulting current rather than the voltage.

FIG. 2 is a schematic block diagram of a conventional photovoltaic apparatus. The photovoltaic apparatus has a photovoltaic panel 20, which contains the active photovoltaic devices, such as those described supra. The photovoltaic panel 20 can be made up of one or multiple photovoltaic cells, photovoltaic modules, or other like photovoltaic devices, singly or multiples, solo or in combination with one another. A frame 22 surrounds the outer edge of the photovoltaic panel that houses the active photovoltaic devices. The frame 22 can be disposed flat or at an angle relative to the plane of the photovoltaic panel 20.

FIG. 3 is a side cross sectional view of the photovoltaic apparatus shown in FIG. 2. In this case, the cross section is taken along the line A-A shown above in FIG. 2. The photovoltaic panel has a photovoltaic device 28 disposed within the frame 22. A glass, plastic, or other translucent barrier 26 is held by the frame 22 to shield the photovoltaic device 28 from an external environment. In some conventional photovoltaic apparatuses, another laminate layer 24 is placed between the photovoltaic device 28 and the translucent barrier 26.

Light impinges through the transparent barrier 26 and strikes the photovoltaic device 28. When the light strikes and is absorbed in the photovoltaic device 28, electricity can be generated much like as described with respect to FIG. 1.

In terms of planar topologies, these geometries are not highly effective in capturing diffuse and/or reflected light, due to their uni-facial makeup (e.g. their ability to capture light emanating from one general direction.) Accordingly, cells or modules that are bifacial (able to capture and convert light from both an “upwards” orientation and a “downwards” orientation) are more effective at utilizing such diffuse or reflected light. In the case of nonplanar solar cells such as cylindrical cells or modules, the cells or modules can capture and utilize light coming from any direction. Accordingly they are labeled as omnifacial devices, and such omnifacial devices are not necessarily strictly limited to those cells or modules having circular cross sections.

Further, the conventional planar topologies are typically characterized by the “sandwich in a sandbox”-type frame as depicted in FIG. 3. The planar topologies are also typically characterized with uni-facial collection characteristics. Accordingly, these conventional geometries are not typically used with reflector constructs.

In most conventional planar topologies, the effective area of the active collection area is substantially equivalent to the entire effective area of the panel. This is since the planar topology dictates that the active devices must utilize as much area as possible in their deployment.

In some photovoltaic (PV) applications, elongated photovoltaic devices or modules can be arranged in a lattice-like arrangement to collect light radiation and transform that collected radiation into electric energy. In these applications, a generic reflector or albedo surface can be used as a backdrop in conjunction with an elongated solar cell or module, where the reflected, diffuse, or secondary light (e.g., the non-direct path light relative to the source) can be collected, especially when used in conjunction with solar cells or modules that have more than one collection surface (e.g. non-uni-facial), or when used with solar cells or modules that are omnifacial in nature (e.g. having a non-planar geometry). However, the geometries of the collection devices are not typically closely tied to the geometries of the reflection devices, resulting in efficiency losses for the associated collection and conversion devices.

The amount of electric power produced by an active device is a function of the effective area of the active device presented to the light source. In a flat active device, the highest effective area is when the light source is at an angle perpendicular to the plane of the device. As the angle to the light source moves away from the normal, the effective area of the flat device diminishes as the included angle moves away from the normal, to an effective area near zero as the source is parallel to the plane of the device. Since a major light source is the sun, if the active devices are static, the angle of incidence to the sun will change as a function of the time of day and as a function of the particular day of the year. Most planar topologies do not typically “track” the path of the light source, either in the day or as a function of the time of year. Most configurations have the panels statically tilted at an angle, where the tilt angle is dependent upon the latitude that the panel is installed. These panels are static in nature and do not move to present the largest surface area to the light source.

In some applications, a flat panel may be mounted on a dynamic frame, allowing the frame to move in accordance with the light source. When this happens, the active surface area can be moved to coordinate with the position of the sun as it rises and sets in the day, and potentially to vary the tilt to compensate for the height of the sun over the horizon as it changes over the course of a year. If this is done, this typically results in larger electric generation over that time. However, in order to do this, expensive control and actuation mechanisms would typically be deployed with a planar topology to track the azimuth between the light source and the planar module, both as a function of the season and as a function of the time of day. This would take time and effort to design, and may require incorporating numerous moving parts that would be prone to breaking.

Further, the use of elongated bifacial solar modules or elongated omnifacial modules is not heavily utilized in the commercial sense. Accordingly, the commercial framing and packaging of large numbers of these types of solar modules has not been heavily emphasized in the commercial arena, if at all. Accordingly, the coupling of frames for elongated solar cells with integral reflective constructs simply has not occurred in conventional commercial photovoltaic solar activities.

### BRIEF DESCRIPTION OF THE DRAWINGS

The accompanying drawings, which are incorporated into and constitute a part of this specification, illustrate one or more embodiments of the present invention and, together with the detailed description, serve to explain the principles and implementations of the invention.

In the drawings:

FIG. 1 is a schematic block diagram of a conventional photovoltaic device.

FIG. 2 is a schematic block diagram of a conventional photovoltaic apparatus.

FIG. 3 is a side cross sectional view of the photovoltaic apparatus shown in FIG. 2.

FIG. 4 is a perspective view of a photovoltaic collection system 30.

FIG. 5 is a cut-away view of the collection system 30 of FIG. 4, detailing the light capture properties of the collection system and an internal structure of the associated photovoltaic module.

FIG. 6 is a perspective view of an embodiment showing multiple elongated photovoltaic modules and an associated concave reflector/concentrator utilized in the context of a framed photovoltaic assembly.

FIG. 7 is a top view of the assembly of FIG. 6.

FIG. 8 is a cut-away view of the assembly of FIG. 7, along the line B-B of FIG. 7.

### DETAILED DESCRIPTION

FIG. 4 is a perspective view of a photovoltaic collection system 30. A photovoltaic collection system 30 has an elongated photovoltaic solar cell or module 32. For the purposes of this disclosure, an elongated module may be described as an integral formation of a plurality of photovoltaic solar cells, coupled together electrically in an elongated structure such as an elongated substrate.

As used in this specification, a photovoltaic module is a device that converts light energy to electric energy, and contains at least one solar cell. A photovoltaic module 32 may be described as having a photovoltaic device having an integral formation of a plurality of photovoltaic solar cells, coupled together electrically in an elongated structure. Examples of such photovoltaic modules that include an integral formation of a plurality of photovoltaic cells are found in U.S. Pat. No. 7,235,736, which is hereby incorporated by reference herein in its entirety. For instance, each photovoltaic cell in an elongated solar module may occupy a portion of an underlying substrate common to the entire photovoltaic module and the cells may be monolithically integrated with each other so that they are electrically coupled to each other either in series or parallel. Alternatively, the elongated photovoltaic module 32 may have one single solar cell that is disposed on a substrate. For the sake of brevity, the current discussion will address the entire photovoltaic structure 32 as a “module”, and it should be understood that this contemplates a device using either a singular elongated solar cell or a series of solar cells disposed along a common elongated non-planar substrate. As will be noted later, a module (photovoltaic module) 32 can also include a protective shell disposed about the actual photovoltaic device. In some embodiments, a photovoltaic module 32 has 1, 2, 3, 4, 5 or more, 20 or more, or 100 or more such solar cells. In general, a photovoltaic module 32 has photovoltaic device with a substrate and a material, operable to convert light energy to electric energy, disposed on the substrate. In some embodiments, such material circumferentially coats the underlying substrate. In some embodiments, such material constitutes the one or more solar cells disposed on the substrate. The material typically comprises multiple layers such as a conducting material, a semiconductor junction, and a transparent conducting material.

For purposes of this specification, an elongated photovoltaic module 32 is one that is characterized by having a longitudinal dimension and a width dimension. In some embodiments of an elongated photovoltaic module 32, the longitudinal dimension exceeds the width dimension by at least a factor of 4, at least a factor of 5, or at least a factor of 6. In some embodiments, the longitudinal dimension of the elongated photovoltaic module 32 is 10 centimeters or greater, 20 centimeters or greater, 100 centimeters or greater. In some embodiments, the width dimension of the elongated photovoltaic module 32 is a diameter of 5 millimeters or more, 1 centimeter or more, 2 centimeters or more, 5 centimeters or more, or 10 centimeters or more. The substrate of the module can be rigid in nature. Rigidity of a material can be measured using several different metrics including, but not limited to, Young's modulus. In solid mechanics, Young's Modulus (E), also known as the Young Modulus, modulus of elasticity, elastic modulus or tensile modulus, is a measure of the stiffness of a given material. It is defined as the ratio, for small strains, of the rate of change of stress with strain. This can be experimentally determined from the slope of a stress-strain curve created during tensile tests conducted on a sample of the material. Young's modulus for various materials is given in the following table.

| | Young's modulus | Young's modulus (E) in |
|---|---|---|
| Material | (E) in GPa | lbf/in² (psi) |
| Rubber (small strain) | 0.01-0.1 | 1,500-15,000 |
| Low density | 0.2 | 30,000 |
| polyethylene | | |
| Polypropylene | 1.5-2 | 217,000-290,000 |
| Polyethylene | 2-2.5 | 290,000-360,000 |
| terephthalate | | |
| Polystyrene | 3-3.5 | 435,000-505,000 |
| Nylon | 3-7 | 290,000-580,000 |
| Aluminum alloy | 69 | 10,000,000 |
| Glass (all types) | 72 | 10,400,000 |
| Brass and bronze | 103-124 | 17,000,000 |
| Titanium (Ti) | 105-120 | 15,000,000-17,500,000 |
| Carbon fiber reinforced | 150 | 21,800,000 |
| plastic (unidirectional, | | |
| along grain) | | |
| Wrought iron and steel | 190-210 | 30,000,000 |
| Tungsten (W) | 400-410 | 58,000,000-59,500,000 |
| Silicon carbide (SiC) | 450 | 65,000,000 |
| Tungsten carbide (WC) | 450-650 | 65,000,000-94,000,000 |
| Single Carbon nanotube | 1,000+ | 145,000,000 |
| Diamond (C) | 1,050-1,200 | 150,000,000-175,000,000 |

In some embodiments of the present application, a material (e.g., a substrate used in module 32) is deemed to be rigid when it is made of a material that has a Young's modulus of 20 GPa or greater, 30 GPa or greater, 40 GPa or greater, 50 GPa or greater, 60 GPa or greater, or 70 GPa or greater. In some embodiments of the present application a material (e.g., a substrate used in module 32) is deemed to be rigid when the Young's modulus for the material is a constant over a range of strains. Such materials are called linear, and are said to obey Hooke's law. Thus, in some embodiments, the substrate used in module 32 is made out of a linear material that obeys Hooke's law. Examples of linear materials include, but are not limited to, steel, carbon fiber, and glass. Rubber, fabric, and soil (except at very low strains) are non-linear materials. In some embodiments, a rigid plastic may be used in the formation of module 32. As defined in Gauthier, 1995, Engineered Materials Handbook—Desk Edition, ASM International, Materials Park, Ohio, p. 55, a rigid plastic is a plastic that has a modulus of elasticity either in flexure or in tension greater than 690 MPa (100 ksi) at 23° C. and 50% relative humidity. In some embodiments, a material is considered rigid when it adheres to the small deformation theory of elasticity, when subjected to any amount of force in a large range of forces (e.g., between 1 dyne and 10⁵ dynes, between 1000 dynes and 10⁶ dynes, between 10,000 dynes and 10⁷ dynes), such that the material only undergoes small elongations or shortenings or other deformations when subject to such force. The requirement that the deformations (or gradients of deformations) of such exemplary materials are small means, mathematically, that the square of either of these quantities is negligibly small when compared to the first power of the quantities when exposed to such a force. Another way of stating the requirement for a rigid material is that such a material does not visibly deform over a large range of forces (e.g., between 1 dyne and 10⁵ dynes, between 1000 dynes and 10⁶ dynes, between 10,000 and 10⁷ dynes). Still another way of stating the requirement for a rigid material is that such a material, over a large range of forces, is well characterized by a strain tensor that only has linear terms. The strain tensor for materials is described in Borg, 1962, Fundamentals of Engineering Elasticity, Princeton, N.J., pp. 36-41, which is hereby incorporated by reference herein in its entirety. In some embodiments, a material is considered rigid when a sample of the material of sufficient size and dimensions does not visibly bend under the force of gravity. The substrate used in the formation of module 32 can be a solid substrate, or a hollow substrate. The substrate can be closed at both ends, only at one end, or open at both ends. The substrate used in the formation of module 32 can be made out of a material that is rigid.

A photovoltaic module can be characterized by a cross-section bounded by any one of a number of shapes. The shapes can be circular, ovoid, or any shape characterized by smooth curved surfaces, or any splice of smooth curved surfaces, or their approximations. The shapes can also be linear in nature, including triangular, rectangular, pentangular, hexagonal, or having any number of linear segmented surfaces. Or, the cross-section can be bounded by any combination of linear surfaces, arcuate surfaces, or curved surfaces. As described herein, for ease of discussion only, an omnifacial circular cross-section is described in conjunction with the described invention. However, it should be noted that any cross-sectional geometry may be used as an elongated photovoltaic module 32 in the practice. Portions of the surface of the photovoltaic module that are occupied by a solar cell are referred to as active surface(s).

Examples of such elongated modules that include an integral formation of a plurality of photovoltaic cells is found in U.S. Pat. No. 7,235,736, filed Mar. 18, 2006, which is hereby incorporated by reference herein in its entirety. For instance, each photovoltaic cell may occupy a portion of an underlying substrate and the cells may be monolithically integrated with each other so that they are electrically coupled to each other either in series or parallel. Alternatively, the elongated photovoltaic module 32 may be one single solar cell that is disposed on a substrate. For the sake of brevity, the current discussion will address the entire photovoltaic structure 32 as a module, and it should be understood that this contemplates either a singular elongated solar cell or a series of solar cells disposed along the elongated structure.

The photovoltaic collection system also has a concentrator 34 associated with it. The concentrator 34 generally forms a concave surface, in which the elongated photovoltaic module 32 is placed. The concentrator 34 is typically made of non-absorbing or low-absorbing material with respect to light energy. In one embodiment, the concentrator 34 can be made with a specular or reflective material. A specular or reflective material may be utilized so that a high percentage of the light that strikes the back surface reflectors are again reflected, minimizing retransmission losses. Or, the concentrator can be made with a diffuse material.

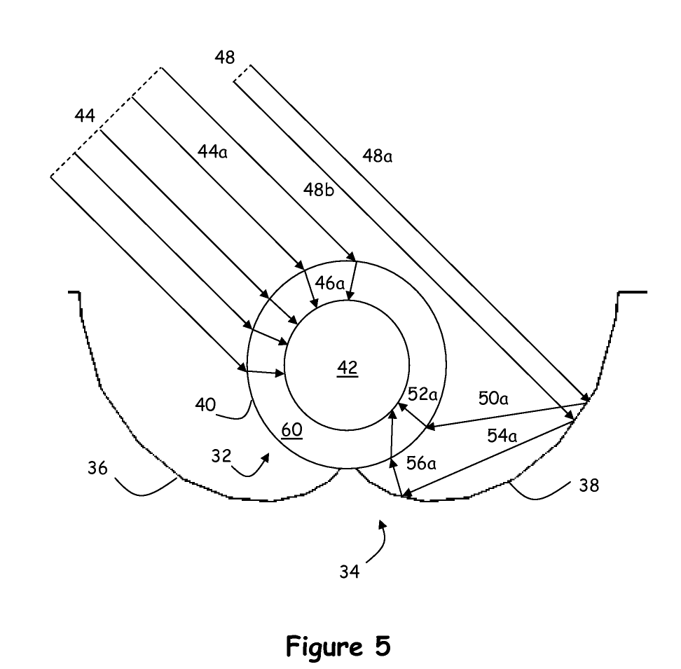

The concentrator 34 is made of a first wall 36 and a second wall 38. Each wall bounds an opposite side of the included elongated photovoltaic module 32. As depicted in FIG. 5, walls 36 and 38 together form a concentrator assembly. In the embodiment depicted, the wall 36 ends at a point tangent or substantially tangent to the elongated photovoltaic module 32. In a similar manner, the wall 38 ends at a point tangent or substantially tangent to the topmost portion of the elongated photovoltaic module 32.

The composition of the concentrator assembly 34 surface (e.g. walls 36 and wall 38) is a specular material in some embodiments. Material with high specular characteristics are desired, since this will reduce reflection loss. In this manner, the walls 36 and 38 can be manufactured from such materials as aluminum or aluminum alloy. In another embodiment, the material can be one that is diffuse.

Examples of such concentrators can be found in U.S. Provisional Patent Application No. 60/898,454, entitled “A Photovoltaic Apparatus Having an Elongated Photovoltaic Device Using an Involute-Based Concentrator,” filed Jan. 30, 2007, which is hereby incorporated by reference herein in its entirety. Examples of such concentrators are also found in U.S. patent application Ser. No. 11/810,283, filed Jun. 5, 2007, which is hereby incorporated by reference herein in its entirety. Other types of concentrators can be used with the items detailed in this specification. Accordingly, although only a limited number of reflective concentrators are described herein, this does not limit the scope of the usage of the apparatus and methods described herein. Such other concentrators should be construed as being operable with and within the scope of the embodiments shown in this specification. In this manner, the system can “self-track”, that is deliver a substantial proportion of light entering the concentrator is redirected to an associated photovoltaic module.

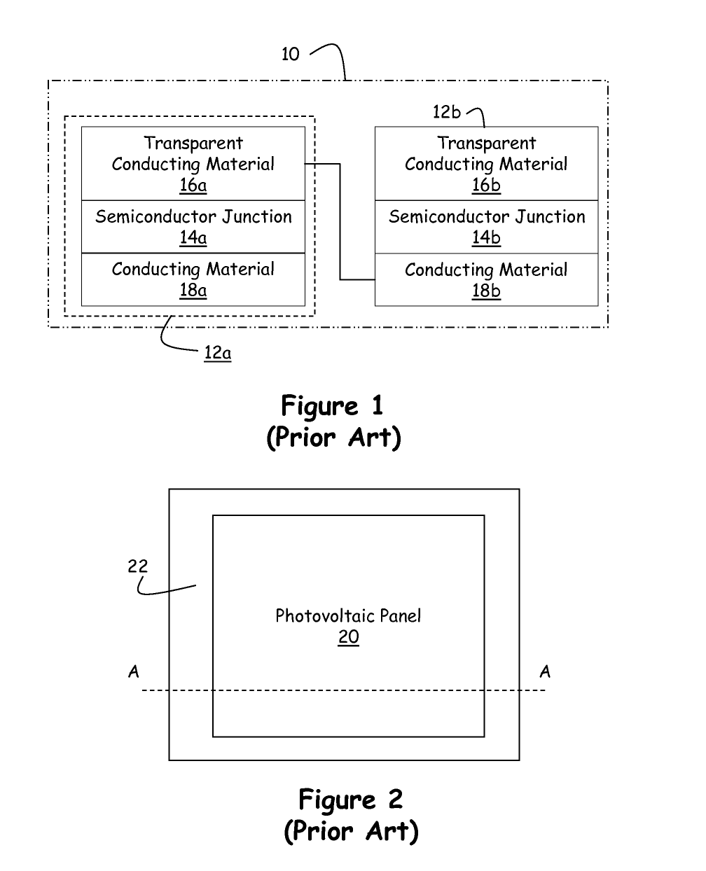

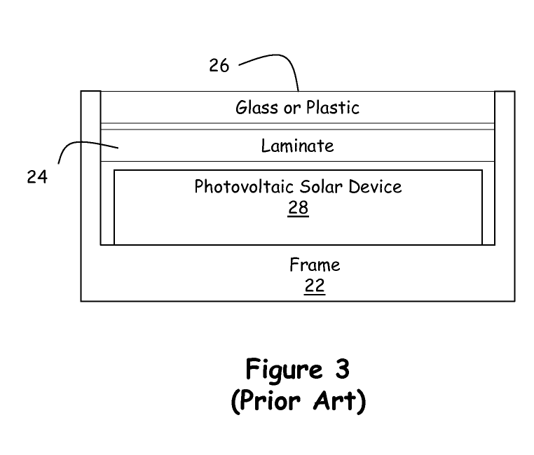

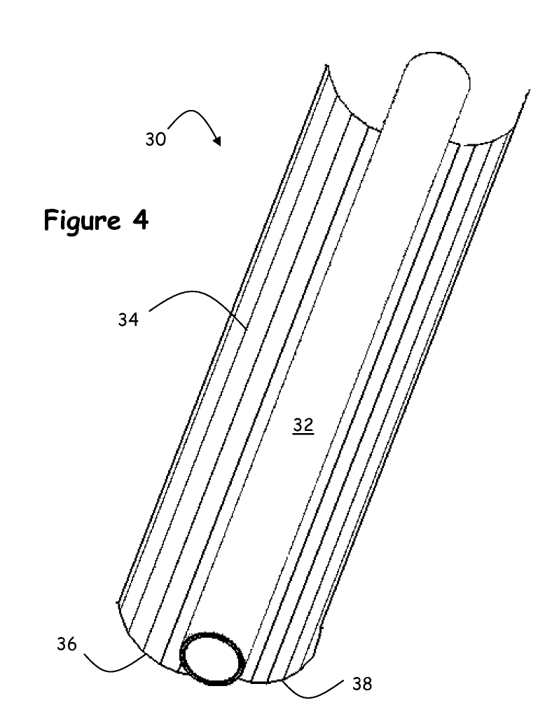

FIG. 5 is a cut-away view of the collection system 30 of FIG. 4, detailing the light capture properties of the collection system 30 and an internal structure of the associated photovoltaic module. The module 32 has an inner photovoltaic device 42. The inner photovoltaic device 42 is a device that collects light energy and converts the collected light energy into electric energy. The inner photovoltaic device 42 can have a structure similar to photovoltaic device 12 in FIG. 1, albeit not in a planar orientation. The photovoltaic device 42 here is pictured as having a circular cross-section, but it should be understood that this is exemplary in nature. In some embodiments, photovoltaic device 42 is any nonplanar geometry.

The module 32 also has an outer shell 40. Many photovoltaic devices are made from semiconductor materials, which can be damaged by exposure to an outside environment. The outer shell 40 protects the inner photovoltaic device from such damage. The outer shell 40 allows light energy to pass from the external environment to the inner photovoltaic device 42.

The outer shell 40 can be made of any material that allows substantial light energy to pass through it. These materials can include, as by way of example, plastics, glasses, and ceramics that allow the passage of light energy. Additional examples of what outer shell 40 can be made of include, but are not limited to urethane polymer, an acrylic polymer, polymethylmethacrylate (PMMA), a fluoropolymer, poly-dimethyl siloxane (PDMS), ethyl vinyl acetate (EVA), perfluoroalkoxy fluorocarbon (PFA), nylon/polyamide, cross-linked polyethylene (PEX), polyolefin, polypropylene (PP), polyethylene terephtalate glycol (PETG), polytetrafluoroethylene (PTFE), thermoplastic copolymer, polyurethane urethane, polyvinyl choloride (PVC), and polyvinylidene fluoride (PVDF). Of course, these or other materials can be used to the extent that they allow at least some light energy to pass and can protect the inner photovoltaic device 42 from an external environment. The outer shell 40 can define an inner volume, in which the photovoltaic device 42 is placed. In some embodiments, the outer shell 40 comprises a plurality of different shell layers and each layer is optionally comprised of a different material.

The outer shell can also serve as a focusing mechanism for the photovoltaic device 42. In this case, the optical properties of the material that makes up the outer shell 40 can be chosen such that light that strikes the outer shell 40 is directed inward to the inner photovoltaic device 42.

In the photovoltaic collection system, the light from a source approaches the opening defined by the wall 36 and the wall 38, and enters into an interior defined by the wall 36 and the wall 38. A light ray 44 enters the photovoltaic collection system 30 and directly strikes the outer shell 40 of the elongated photovoltaic module 32.

The light ray 44a strikes the outer shell 40, where it is refracted towards the inner photovoltaic device 42, such as shown by a refracted light ray 46a. When it strikes the inner photovoltaic device 42, the refracted light ray 46a is absorbed by the inner photovoltaic device 42 and converted to electric energy.

Other light rays 44 are shown similarly refracted towards the inner photovoltaic device 42. An elongated photovoltaic module 32 thusly constructed serves to enhance the effective surface area of the inner photovoltaic device (e.g. the diameter of the inner photovoltaic device 42) to one related to the diameter of the outer shell 40.

Another light ray 48a enters the photovoltaic collection system depicted in FIG. 5 and strikes the wall 38. The wall 38 redirects the light ray 48a thereby forming redirected light ray 50a. As illustrates in FIG. 5, the redirected light ray 50a is redirected from its original path to one that strikes the photovoltaic module 32, albeit from a direction other than the plane directly facing the opening defined by the wall 36 and the wall 38.

In a manner similar to the description above relating to the light ray 44a, the redirected light ray 50a strikes the outer shell 40, where it is refracted towards the inner photovoltaic device 42, such as shown by a refracted light ray 52a. When the light ray 52a strikes the inner photovoltaic device 42, the refracted light ray 42a is absorbed by the inner photovoltaic device 42 and converted to electric energy.

It should be noted that the reflector 34 can produce light paths that take more than one reflection to be redirected to the elongated photovoltaic module 32. One such multi-reflection can be shown in the sequence of light rays 48b, 54a, and 56a. Although light paths of one and two reflections are shown in FIG. 5, it should be noted that the concentrator may be such that any positive number of reflections for a light path that reaches the elongated photovoltaic module 32 can be contemplated.

Thus, the system as depicted can produce electric energy from light that directly strikes the elongated photovoltaic module 32 from the initial source without any redirection on the concentrator 34. Further, the system as depicted can produce electric energy from light that is not necessarily directed at the forward face of the elongated photovoltaic module 32. This is advantageous, because, as noted in the background section, conventional photovoltaic collection designs are limited to the use of light directed at the forward face of the solar panel. Further, the aspect of the elongated photovoltaic module 32 corresponding to multiple light energy collection and/or conversion areas allows redirected light to be collected and transformed on the side facing of the module, the back facing of the module, or both. In this manner, reflected light collection and transformation can be substantially improved over typical conventional photovoltaic systems.

A distinct advantage of the apparatus is that the photovoltaic modules may have, for example, a first active surface that receives direct unreflected light, and possibly an additional one or more second active surfaces that receive light that has been reflected or otherwise redirected from the first and second walls of corresponding concentrator assemblies. Thus, light energy originating from any of multiple different orientations with respect to a cross section of an elongated photovoltaic assembly 32 can strike an active surface of the elongated photovoltaic module 32 in an orthogonal manner. In some embodiments, light energy originating from any orientation or non-direct source with respect to a cross section of an elongated photovoltaic assembly 32 can strike an active surface of the elongated photovoltaic assembly 32 in an orthogonal manner. In some embodiments, a photovoltaic module 32 is omnifacial even when the active zone of the solar cells of the photovoltaic module 32 does not span the complete circumference of the photovoltaic module 32 substrate. In some embodiments, a photovoltaic module 32 is deemed to be omnifacial provided that the active zone of one or more solar cells of the photovoltaic module 32 collectively span at least thirty percent, at least forty percent, at least fifty percent, at least sixty percent, at least seventy percent, at least eighty percent, at least ninety percent, or all of the circumference of the substrate of the elongated photovoltaic module 32. As noted, there may be a single solar cell or a plurality of solar cells spanning the requisite circumference of the substrate of the photovoltaic module 32. As used in this description, photovoltaic modules 32 in which there are a plurality of solar cells spanning the requisite circumference of the substrate are termed “multi-facial” photovoltaic modules because they employ more than one light collecting surface, each oriented in a specific orientation. Accordingly, in one embodiment the walls 36/38 of the concentrator 34 can be thought of as defining a planar region. Light coming directly from the source into the concentrator 34 will have a vertical component (relative to the concentrator) normal to the planar region traveling downwards. A proportion of the light that is “bounced” from the concentrator 34 will typically have a component normal to the planar region that is opposite in sign than that of direct incoming light or, in other words, its normal component to the planar region is anti-parallel to that of the directly impinging light. Accordingly the bifacial or multi-facial aspects used in some embodiments are operable to collect both direct light sources (traveling inwards and having the vertical component to the planar region being of one sign) and light that has been redirected to having its vertical component having the opposite sign of the direct light.

In one embodiment, the shape of the wall 36 and the wall 38 are defined as involutes or substantially the involutes of the sides of the elongated photovoltaic module 32. An involute is a shape that is dependent upon the shape of another object, where that object is made up of substantially smooth curves, or from a series of faces that approximate a smooth curve. It will be appreciated that walls 36 and 38 may be made from separate pieces. In alternative embodiments, walls 36 and 38 may be molded or formed as a single piece. In such embodiments, the single piece includes sections 36 and 38 with a connector section that joins the two sections together thereby forming a single piece.

An example of photovoltaic modules having omnifacial or multi-facial characteristics working in conjunction with an outer shell can be found in U.S. Pat. No. 7,235,736, as well as U.S. patent application Ser. Nos. 11/799,940 and 11/799,956 each entitled “Monolithic Integration of Non-planar solar cells” and each filed May 3, 2007, each of which is hereby incorporated by reference herein in its entirety. Notwithstanding the current description including involute-based reflectors, the current system need not be limited to those reflectors that have a shape, either in whole or in part, based on the involute of the elongated photocoltaic module 32. As has been previously noted, the reflector can be of any shape such that incoming light is reflected towards an elongated photovoltaic module.

The volume 60 between the inner photovoltaic 42 device and the outer shell 40 can be filled with a substance that further protects the inner photovoltaic device. In some embodiments the volume 60 is an annular volume. An example of photovoltaic modules having omnifacial or multi-facial characteristics working in conjunction with an outer shell with materials within the annular space can be found in U.S. Pat. No. 7,235,736, as well as U.S. patent application Ser. Nos. 11/799,940 and 11/799,956 each entitled “Monolithic Integration of Non-planar solar cells” and each filed May 3, 2007, as well as U.S. patent application Ser. No. 11/378,847, entitled “Elongated Photovoltaic Cells in Tubular Casings,” filed Mar. 18, 2006, U.S. patent application Ser. No. 11/821,524, entitled “Elongated Photovoltaic Cells in Casings with a Filling Layer,” filed Jun. 22, 2007, and U.S. patent application Ser. No. 11/544,333 entitled “Sealed Photovoltaic Apparatus, filed Oct. 6, 2006, each of which is hereby incorporated by reference herein in its entirety. Of course, in some cases, the volume 60 between the inner photovoltaic 42 device and the outer shell 40 can be another material, such as a non-reactive gas.

In some embodiments, as noted previously, the walls 36 and 38 can be wholly an involute shape, partially an involute shape, or have no relation to the involute shape. Moreover, in some embodiments involving the involute shape, only a portion of the wall 36 and/or wall 38 may form the involute of a corresponding evolute of the module 32. For example, if the wall 36 and/or wall 38 are considered in terms of the curve swept out by the respective wall as illustrated, in some embodiments, fifty percent or more of the curve swept out by wall 36 and/or wall 38 is an involute of a corresponding evolute of the module 32. In some embodiments, sixty percent or more, seventy percent or more, eighty percent or more, ninety percent or more, or the entire curve swept out by the wall 36 and/or wall 38 is an involute of a corresponding evolute of the module 32. The balance of the curve swept out by wall 36 and/or 38 in such embodiments can adopt any shape that will facilitate the function of the concentrator 34, either in its role as a concentrator, or in an auxiliary role as a physical support for the module 32, to link together different concentrator assemblies, to link the concentrator into the frame, or to further physically integrate the module 32 into a planar array of modules

In some cases, the height at which the concentrator 34 surface ends corresponds to the topmost portion of the photovoltaic module 32 using the orientations of FIG. 5 for reference. In another case, the height at which the concentrator 34 surface ends corresponds to a point that exceeds the height of the topmost portion of the photovoltaic module 32 by up to 10% of the total height h of the module 32 using FIG. 5 for reference. In some embodiments the side of the concentrator 34 ends at a height corresponding to the midpoint diameter of the module 32 in embodiments where the module 32 is cylindrical or approximately cylindrical. Other potential ending heights for the side of the concentrator 34 can also be d/2, d/4, 3d/4, 3d/8, 5d/8, 7d/8, 5/16d, 7/16d, 9d/16, 11d/16, 13d/16, and 15d/16, between d/4 and d/2, between d/2 and 3d/4, between 3d/8 and 3d/4, between 3d/8 and 5d/8, between 5/16d and 7d/8, between 5/16d and 7/16d, between 7/16d and 9d/16, between 9d/16 and 11d/16, between 11d/16 and 13d/16, or between 13d/16 and 15d/16 where d is the height h of the photovoltaic module 32 as illustrated in FIG. 5. Any height between d/2 and d can be thought of as providing very good energy conversion ratios. One should note that the height h of concentrator 34 can be any height.

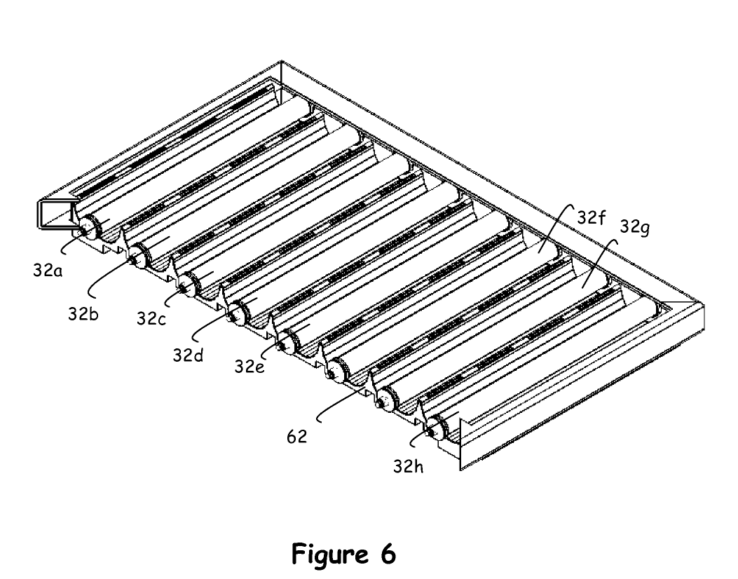

FIG. 6 is a perspective view of an embodiment showing multiple elongated photovoltaic modules 32 and an associated concentrator that includes a concave portion for each module 32. As illustrated in FIG. 6, the device is preferably utilized in the context of a framed photovoltaic assembly, where the reflective concentrator is integrated into the frame. The apparatus illustrated in FIG. 6 is characterized by having a plurality of photovoltaic modules 32a-h. In other embodiments, the apparatus has two or more photovoltaic modules 32, 10 or more photovoltaic modules 32, 100 or more photovoltaic modules 32, 1000 or more photovoltaic modules 32, between 2 and 10,000 photovoltaic modules 32, or less than 500 photovoltaic modules 32. It should be noted that any number of photovoltaic modules could be utilized.

Referring to FIG. 6, elongated photovoltaic modules 32a-h are disposed within a frame. The frame can be made up of at least two cross-supports. In FIG. 6, to gain perspective of the construction, one of the cross-supports has been deleted in order to see detail. In some embodiments, the supports have a plurality of electrical contacts (not shown) arranged along the length of the support. Such electrical contacts may be formed by conducting wires, conducting glue, or any other conducting material useful for drawing current from photovoltaic modules. In some embodiments each of the photovoltaic modules is electrically coupled to an electric contract in the plurality of electric contacts disposed within the supports. Because the elongated solar modules 32 are disposed within frame, a lattice-like assembly can be constructed. This lattice-like assembly can be disposed on a surface to collect light energy and transform that light energy to electric energy. The elongated photovoltaic modules 32a-h in this case are omnifacial (e.g. each have one or more solar cells circumferentially, or partially circumferentially, disposed on a common non-planar substrate). Further, the elongated photovoltaic modules 32 need not all be omnifacial or multi-facial, and a final assembly can comprise various combinations of photovoltaic modules 32

As mentioned above, a concentrator 62 is also provided with the frame. The concentrator is integrated within the frame such that portions of the concentrator are disposed to the sides and beneath the photovoltaic modules 32a-h. The concentrator 62 can be mechanically attached to the cross-supports. For example, the cross-supports can have slots associated with them that allow the concentrator to be inserted and attached to the frame.

As described in this specification, the shape of the concentrator 62 can be specifically designed to reflect the retransmitted light in the direction of a particular elongated photovoltaic module. Advantageously, this can be accomplished without mechanical tracking systems.

The concentrator 62 can be made as a one-piece construction, formed to the appropriate shape. Or, the concentrator 62 can be made up of sub-units, as discussed below.

As depicted in FIG. 6, the frame of the assembly has lateral supports. The concentrator 62 can be designed to also fit with either lateral support, or both. It should be noted that while the lateral supports provide added strength to the solar panel construct, they are optional in nature.

Additionally, it should be noted that the photovoltaic modules 32a-h are shown having an orientation perpendicular to the cross-supports and/or the lateral supports. It should be noted that the photovoltaic modules 32a-h can have any angular orientation with respect to the cross-supports or lateral supports, and this description should be construed as implementing any angular orientation between the elongated photovoltaic modules 32a-h and the cross-supports. For example, each photovoltaic module 32 may intersect a cross-support at an angle other than the perpendicular, such as an obtuse angle and/or an acute angle. Furthermore, as illustrated in FIG. 6, the photovoltaic modules 32 are parallel with respect to each other. While this geometry is contemplated as a preferred embodiment, the disclosure is not limited to such configurations. In some embodiments, the photovoltaic modules 32 are not exactly parallel to each other. In some embodiments, the photovoltaic modules 32 are not parallel to each other. Moreover, as illustrated in FIG. 6, the photovoltaic modules 32 are coplanar. However, the disclosure is not limited to such embodiments. In some embodiments, the photovoltaic modules 32 are positioned at different heights within the frame, with some being higher in the frame, using the orientation of FIG. 6 where the top of the page is higher than the bottom of the page, as a reference.

As noted previously, the concentrator can be implemented in a single fabricated panel, such as panel 62. Or, the concentrator can be made from individual reflectors being coupled together. Methods and various constructions of the frame, the unitary concentrator, and those made from a plurality of pieces can be found in U.S. Patent Application No. 60/859,212, entitled “Fiber Reinforced Solar Panel Frame”, filed Nov. 15, 2006; 60/859,212, entitled “Arrangement for Securing Elongated Solar Cells,” filed Nov. 15, 2006; 60/859,188, entitled “Reinforced Solar Cell Frames,” filed Nov. 15, 2006; and 60/859,215, entitled “Solar Panel Frame”, filed Nov. 15, 2006, each of which is hereby incorporated by reference herein in its entirety.

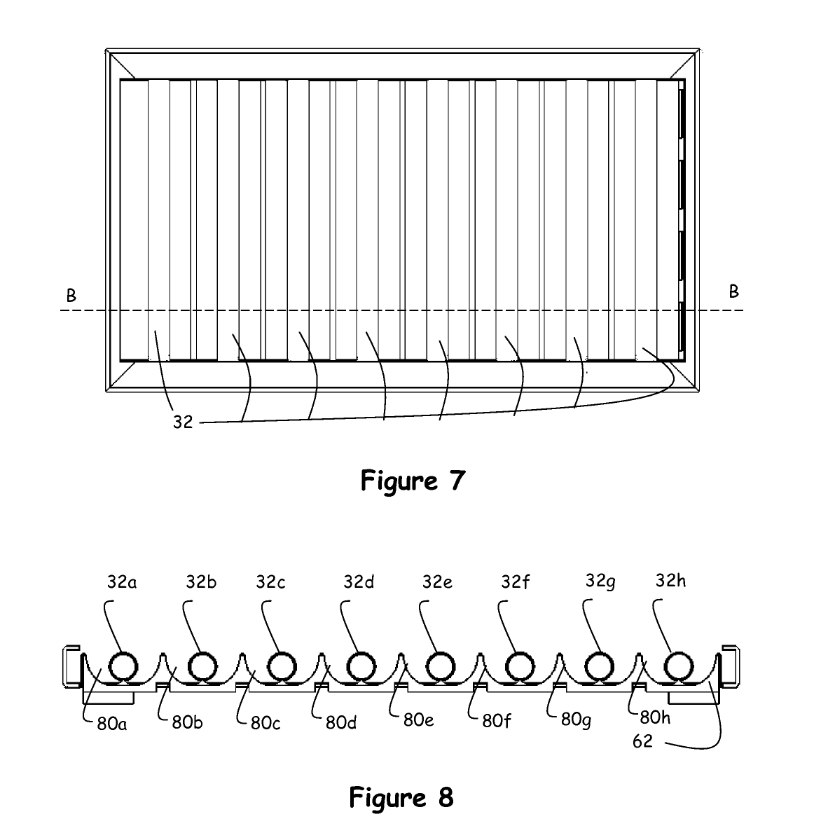

FIG. 7 is a top view of the assembly of FIG. 6. In this Figure, the photovoltaic modules 32 are shown spaced apart from one another. The spaces between the photovoltaic modules 32 are shown to be “filled” with the concentrator, such that a substantial proportion of light that impinges on the area of the framed assembly is directed to the photovoltaic modules 32a-h.

FIG. 8 is a cut-away view of the assembly of FIG. 7, along the line B-B of FIG. 7. FIG. 8 shows some of the geometric relationships between the photovoltaic modules 32a-h and the concentrator 62 in accordance with an embodiment in which the photovoltaic modules 32 run substantially parallel with respect to each other and are su bstantially co-planar. As illustrated in FIG. 8, for each photovoltaic module 32, there is a substantially concave carve-out 80 in the concentrator 62. This carve-out is referred to herein as a concentrator assembly. As illustrated in FIG. 8, each carve-out (concentrator assembly 80) comprises a first surface and a second surface (respectively a left surface and a right surface using the orientations provided in FIG. 8). The first surface and the second surface form the concave structure 80 that is operable to transmit light energy that enters the concave structure to the associated particular photovoltaic module 32. The first surface and the second surface of each carve-out (concentrator assembly 80) each comprise substantially the shape of the involute of the particular photovoltaic module 32 associated with the respective concentrator assembly. As illustrated in FIG. 8 and using the orientations provided in FIG. 8 as a reference, the first surface and the second surface of each concentrator assembly 80 extends no more than the height of the particular photovoltaic module 32 associated with the respective concentrator assembly 80.

In context, the one or more solar cells that are on the above-described photovoltaic units 32 can be made of various materials, and in any variety of manners. Examples of compounds that can be used to produce the solar cells can include Group IV elemental semiconductors such as: carbon (C), silicon (Si) (both amorphous and crystalline), germanium (Ge); Group IV compound semiconductors, such as: silicon carbide (SiC), silicon germanide (SiGe); Group III-V semiconductors, such as: aluminum antimonide (AlSb), aluminum, arsenide (AlAs), aluminum nitride (AlN), aluminum phosphide (AlP), boron nitride (BN), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP); Group III-V ternary semiconductor alloys, such as: aluminum gallium arsenide (AlGaAs, AlxGa1-xAs), indium gallium arsenide (InGaAs, InxGa1-xAs), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb); Group III-V quaternary semiconductor alloys, such as: aluminum gallium indium phosphide (AlGaInP, also InAlGaP, InGaAlP, AlInGaP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN); Group III-V quinary semiconductor alloys, such as: gallium indium nitride arsenide antimonide (GaInNAsSb); Group II-VI semiconductors, such as: cadmium selenide (CdSe), cadmium sulfide (CdS), cadmium telluride (CdTe), zinc oxide (ZnO), zinc selenide (ZnSe), zinc sulfide (ZnS), zinc telluride (ZnTe); Group II-VI ternary alloy semiconductors, such as: cadmium zinc telluride (CdZnTe, CZT), mercury cadmium telluride (HgCdTe), mercury zinc telluride (HgZnTe), mercury zinc selenide (HgZnSe); Group I-VII semiconductors, such as: cuprous chloride (CuCl); Group IV-VI semiconductors, such as: lead selenide (PbSe), lead sulfide (PbS), lead telluride (PbTe), tin sulfide (SnS), tin telluride (SnTe); Group IV-VI ternary semiconductors, such as: lead tin telluride (PbSnTe), thallium tin telluride (Tl₂SnTe₅), thallium germanium telluride (Tl₂GeTe₅); Group V-VI semiconductors, such as: bismuth telluride (Bi₂Te₃); Group II-V semiconductors, such as: cadmium phosphide (Cd₃P₂), cadmium arsenide (Cd₃As₂), cadmium antimonide (Cd₃Sb₂), zinc phosphide (Zn₃P₂), zinc arsenide (Zn₃As₂), zinc antimonide (Zn₃Sb₂); layered semiconductors, such as: lead(II) iodide (PbI₂), molybdenum disulfide (MoS₂), gallium selenide (GaSe), tin sulfide (SnS), bismuth sulfide (Bi₂S₃); others, such as: copper indium gallium selenide (CIGS), platinum silicide (PtSi), bismuth(III) iodide (BiI3), mercury(II) iodide (HgI₂), thallium(I) bromide (TlBr); or miscellaneous oxides, such as: titanium dioxide anatase (TiO₂), copper(I) oxide (Cu₂O), copper(II) oxide (CuO), uranium dioxide (UO₂), or uranium trioxide (UO₃). This listing is not exclusive, but exemplary in nature. Further, the individual grouping lists are also exemplary and not exclusive. Accordingly, this description of the potential semiconductors that can be used in the solar cells of the photovoltaic units 32 should be regarded as illustrative.

The foregoing materials may be used with various dopings to form a semiconductor junction. For example, a layer of silicon can be doped with an element or substance, such that when the doping material is added, it takes away (accepts) weakly-bound outer electrons, and increases the number of free positive charge carriers (e.g. a p-type semiconductor.) Another layer can be doped with an element or substance, such that when the doping material is added, it gives (donates) weakly-bound outer electrons addition and increases the number of free electrons (e.g. an n-type semiconductor.) An intrinsic semiconductor, also called an undoped semiconductor or i-type semiconductor, can also be used. This intrinsic semiconductor is typically a pure semiconductor without any significant doping. The intrinsic semiconductor, also called an undoped semiconductor or i-type semiconductor, is a pure semiconductor without any significant dopants present. The semiconductor junction layer can be made from various combinations of p-, n-, and i-type semiconductors, and this description should be read to include those combinations.

The solar cells of the elongated photovoltaic modules 32 may be made in various ways and have various thicknesses. The solar cells as described herein may be so-called thick-film semiconductor structures or a so-called thin-film semiconductor structures.

Thus, a photovoltaic assembly with elongated photovoltaic devices and integrated involute-based reflectors is described and illustrated. Those skilled in the art will recognize that many modifications and variations of the present invention are possible without departing from the invention. Of course, the various features depicted in each of the figures and the accompanying text may be combined together.

As used herein, the term “direct light energy” means light that has not been redirected from a concentrator.

Referring to FIG. 5, one aspect of the application provides an assembly for converting light energy to electric energy. The assembly comprises an outer shell 40 defining an inner volume 60. The outer shell 40 is operable to allow light to enter the inner volume 60. The outer shell 40 is characterized by having a longitudinal dimension and a cross-sectional dimension. In some embodiments, the longitudinal dimension is greater than two, three, four, five or six times the cross-sectional dimension. The assembly further comprises a substrate disposed within the inner volume. The outer shell 40 and the substrate define an annular volume 60 between them. A first material is disposed on the substrate and is operable to convert light energy to electric energy. This first material has an index of refraction greater than that of air. The substrate and the first material together form inner photovoltaic device 42. A second material is disposed in the annular volume. In some embodiments, the second material has an index of refraction equal to or less than that of the first material. In some embodiments, the refractive index of the second material occupying the inner volume 60 is larger than the refractive index of the outer shell 40 so that light is refracted and bent towards inner photovoltaic device 42. In this such instances, incident light on outer shell 40 will be bent towards the inner photovoltaic device. In practice, however, the second material occupying inner volume 60 is made of a fluid-like material (albeit sometimes very viscous fluid-like material) such that loading of photovoltaic devices 42 into outer shell 40 may be achieved as described above. In practice, efficient solar radiation absorption is achieved by choosing a second material that has refractive index close to that of the outer shell 40. In some embodiments, materials that form outer shell 40 comprise transparent materials (either glass or plastic or other suitable materials) with refractive indices around 1.5. For example, fused silica glass has a refractive index of 1.46. Borosilicate glass materials have refractive indices between 1.45 and 1.55 (e.g., PYREX® glass has a refractive index of 1.47). Flint glass materials with various amounts of lead additive have refractive indices between 1.5 and 1.9. Common plastic materials have refractive indices between 1.46 and 1.55. The assembly for converting light energy to electric energy further comprises a concentrator assembly 34 comprising a first surface 36 and a second surface 38, the first surface 36 and the second surface 38 forming a concave structure operable to transmit light energy that enters the concave structure to the outer shell 40.

Reflection and refraction are inter-related phenomenon. Fresnel's equations describe the intensity of reflected waves and refracted waves when an electromagnetic wave strikes an interface between two materials. According to Fresnel's equations, in the special case of an incident wave that is normal (perpendicular) to the surface, the reflection coefficient R and transmission (refracted wave) coefficient T are:

$$R = {( \frac{{η}_{1} - {η}_{2}}{{η}_{1} + {η}_{2}} )}^{2} ; T = \frac{4 {η}_{1} {η}_{2}}{{( {η}_{1} + {η}_{2} )}^{2}}$$

where η₁ and η₂ are the refractive indices of the two bordering media 1 and 2. As can be seen, when η₂ is much larger than η₁, the reflection coefficient R becomes larger. This means that more light is reflected (and thus less light refracted by transmission) when the difference between the refractive indexes is larger than when the difference is smaller. This extends beyond the special case of normal incidence and affects all incident beams regardless of the angle of incidence. So, although a larger difference in value between refractive indexes of outer shell 40, the second material, and inner photovoltaic device 42 will result in a higher degree of refraction towards interior layers of the solar cells of the inner photovoltaic device 42, it also results in more reflection of light away from interior layers of the solar cells of the inner photovoltaic device 42. In some embodiments, these two competing effects are preferably balanced in order to achieve maximum exposure of interior layers of the solar cells of the inner photovoltaic device 42. One method of balancing these effects is to choose the second material that is used to fill space 60 based on the refractive index η₆₀ of the material. In some embodiments, a value of η₆₀ is chosen such that the aggregate reflection of light at the interface between (i) shell 40 and the second material (η₆₀) and (ii) the second material (η₆₀) and inner photovoltaic device 42 is minimized. In some embodiments, η₆₀ is chosen to be approximately halfway between the refractive index of the inner photovoltaic device 42 and the outer shell 40. For example, if the outer shell has a refractive index of 1.2 and the outermost layer of the inner photovoltaic device 42 has a refractive index of 1.9, then η₆₀, the refractive index of the second material, would be chosen to be approximately 1.55. In other embodiments, η₆₀ is chosen to be approximately equal to either the refractive index of the outermost layer of the inner photovoltaic device 42 or the refractive index of the outer shell 40. For example, when η₆₀ is approximately equal to the refractive index of the outer shell, there is very little reflection or refraction that occurs at the interface between the outer shell 40 and the second material occupying space 60. This means that the interface does not noticeably alter the trajectory or intensity of light passing through the interface. Thus it is only at the interface between the second material and the transparent conductive layer of the inner photovoltaic device 42 where light is reflected and refracted.

In some embodiments, a given index of refraction is approximately equal to a reference index of refraction when the given index of refraction is within 0.5, within 0.4, within 0.3, within 0.2, 0.1, with 0.05, or with 001 units of the reference index of refraction. For example, consider the case where the given index of refraction is x, the reference index of refraction is y, and the term “approximately equal” in accordance with one embodiment is 0.1. In this case, y−0.1≦x≦y+0.1. On the other hand, if the term “approximately equal” in accordance with one embodiment is 0.2, y−0.2≦x≦y.

Chemical composition of the second material used to fill space 60. The second material used to fill annular layer 60 can be made of sealant such as ethylene vinyl acetate (EVA), silicone, silicone gel, epoxy, polydimethyl siloxane (PDMS), RTV silicone rubber, polyvinyl butyral (PVB), thermoplastic polyurethane (TPU), a polycarbonate, an acrylic, a fluoropolymer, and/or a urethane. In some embodiments, the second material is a Q-type silicone, a silsequioxane, a D-type silicon, or an M-type silicon.

In one embodiment, the substance used to form the second material comprises a resin or resin-like substance, the resin potentially being added as one component, or added as multiple components that interact with one another to effect a change in viscosity. In another embodiment, the resin can be diluted with a less viscous material, such as a silicon-based oil or liquid acrylates. In these cases, the viscosity of the initial substance can be far less than that of the resin material itself. In one example, a medium viscosity polydimethylsiloxane mixed with an elastomer-type dielectric gel can be used to make the second material. In one case, as an example, a mixture of 85% (by weight) Dow Corning 200 fluid, 50 centistoke viscosity (PDMS, polydimethylsiloxane); 7.5% Dow Corning 3-4207 Dielectric Tough Gel, Part A—Resin; and 7.5% Dow Corning 3-4207 Dielectric Tough Gel, Part B—Catalyst is used to form the second material. Other oils, gels, or silicones can be used to produce much of what is described in the specification, and accordingly this specification should be read to include those other oils, gels and silicones to generate the described second material. Such oils include silicon based oils, and the gels include many commercially available dielectric gels. Curing of silicones can also extend beyond a gel like state. Commercially available dielectric gels and silicones and the various formulations are contemplated as being usable in this application.

In one example, the second material is 85%, by weight, polydimethylsiloxane polymer liquid, where the polydimethylsiloxane has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes (all viscosity values given in this application for compositions assume that the compositions are at room temperature). Thus, there may be polydimethylsiloxane molecules in the polydimethylsiloxane polymer liquid with varying values for n provided that the bulk viscosity of the liquid falls in the range between 50 centistokes and 100,000 centistokes. Bulk viscosity of the polydimethylsiloxane polymer liquid may be determined by any of a number of methods known to those of skill in the art, such as using a capillary viscometer. Further, the composition includes 7.5%, by weight, of a silicone elastomer comprising at least sixty percent, by weight, dimethylvinyl-terminated dimethyl siloxane (CAS number 68083-19-2) and between 3 and 7 percent by weight silicate (New Jersey TSRN 14962700-537 6P). Further, the composition includes 7.5%, by weight, of a silicone elastomer comprising at least sixty percent, by weight, dimethylvinyl-terminated dimethyl siloxane (CAS number 68083-19-2), between ten and thirty percent by weight hydrogen-terminated dimethyl siloxane (CAS 70900-21-9) and between 3 and 7 percent by weight trimethylated silica (CAS number 68909-20-6).

In some embodiments, the second material is formed by soft and flexible optically suitable material such as silicone gel. For example, in some embodiments, the second material is formed by a silicone gel such as a silicone-based adhesives or sealants. In some embodiments, the second material is formed by GE RTV 615 Silicone. RTV 615 is an optically clear, two-part flowable silicone product that requires SS4120 as primer for polymerization (RTV615-1P), both available from General Electric (Fairfield, Conn.). Silicone-based adhesives or sealants are based on tough silicone elastomeric technology. The characteristics of silicone-based materials, such as adhesives and sealants, are controlled by three factors: resin mixing ratio, potting life and curing conditions.

Advantageously, silicone adhesives have a high degree of flexibility and very high temperature resistance (up to 600° F.). Silicone-based adhesives and sealants have a high degree of flexibility. Silicone-based adhesives and sealants are available in a number of technologies (or cure systems). These technologies include pressure sensitive, radiation cured, moisture cured, thermo-set and room temperature vulcanizing (RTV). In some embodiments, the silicone-based sealants use two-component addition or condensation curing systems or single component (RTV) forms. RTV forms cure easily through reaction with moisture in the air and give off acid fumes or other by-product vapors during curing.

Pressure sensitive silicone adhesives adhere to most surfaces with very slight pressure and retain their tackiness. This type of material forms viscoelastic bonds that are aggressively and permanently tacky, and adheres without the need of more than finger or hand pressure. In some embodiments, radiation is used to cure silicone-based adhesives. In some embodiments, ultraviolet light, visible light or electron bean irradiation is used to initiate curing of sealants, which allows a permanent bond without heating or excessive heat generation. While UV-based curing requires one substrate to be UV transparent, the electron beam can penetrate through material that is opaque to UV light. Certain silicone adhesives and cyanoacrylates based on a moisture or water curing mechanism may need additional reagents properly attached to the inner photovoltaic module 42 without affecting the proper functioning of the inner photovoltaic module 42. Thermo-set silicone adhesives and silicone sealants are cross-linked polymeric resins cured using heat or heat and pressure. Cured thermo-set resins do not melt and flow when heated, but they may soften. Vulcanization is a thermosetting reaction involving the use of heat and/or pressure in conjunction with a vulcanizing agent, resulting in greatly increased strength, stability and elasticity in rubber-like materials. RTV silicone rubbers are room temperature vulcanizing materials. The vulcanizing agent is a cross-linking compound or catalyst. In some embodiments in accordance with the present application, sulfur is added as the traditional vulcanizing agent.

In one example, the second material used to fill space 60 is silicon oil mixed with a dielectric gel. The silicon oil is a polydimethylsiloxane polymer liquid, whereas the dielectric gel is a mixture of a first silicone elastomer and a second silicone elastomer. As such, the composition used to form the space 60 is X %, by weight, polydimethylsiloxane polymer liquid, Y %, by weight, a first silicone elastomer, and Z %, by weight, a second silicone elastomer, where X, Y, and Z sum to 100. Here, the polydimethylsiloxane polymer liquid has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes. Thus, there may be polydimethylsiloxane molecules in the polydimethylsiloxane polymer liquid with varying values for n provided that the bulk viscosity of the liquid falls in the range between 50 centistokes and 100,000 centistokes. The first silicone elastomer comprises at least sixty percent, by weight, dimethylvinyl-terminated dimethyl siloxane (CAS number 68083-19-2) and between 3 and 7 percent by weight silicate (New Jersey TSRN 14962700-537 6P). Further, the second silicone elastomer comprises at least sixty percent, by weight, dimethylvinyl-terminated dimethyl siloxane (CAS number 68083-19-2), between ten and thirty percent by weight hydrogen-terminated dimethyl siloxane (CAS 70900-21-9) and between 3 and 7 percent by weight trimethylated silica (CAS number 68909-20-6). In this embodiment, X may range between 30 and 90, Y may range between 2 and 20, and Z may range between 2 and 20, provided that X, Y and Z sum to 100 percent.

In another example, the second material used to fill the layer 60 is silicon oil mixed with a dielectric gel. The silicon oil is a polydimethylsiloxane polymer liquid, whereas the dielectric gel is a mixture of a first silicone elastomer and a second silicone elastomer. As such, the composition used to form the second material is X %, by weight, polydimethylsiloxane polymer liquid, Y %, by weight, a first silicone elastomer, and Z %, by weight, a second silicone elastomer, where X, Y, and Z sum to 100. Here, the polydimethylsiloxane polymer liquid has the chemical formula (CH₃)₃SiO[SiO(CH₃)₂]ₙSi(CH₃)₃, where n is a range of integers chosen such that the polymer liquid has a volumetric thermal expansion coefficient of at least 500×10⁻⁶/° C. Thus, there may be polydimethylsiloxane molecules in the polydimethylsiloxane polymer liquid with varying values for n provided that the polymer liquid has a volumetric thermal expansion coefficient of at least 960×10⁻⁶/° C. The first silicone elastomer comprises at least sixty percent, by weight, dimethylvinyl-terminated dimethyl siloxane (CAS number 68083-19-2) and between 3 and 7 percent by weight silicate (New Jersey TSRN 14962700-537 6P). Further, the second silicone elastomer comprises at least sixty percent, by weight, dimethylvinyl-terminated dimethyl siloxane (CAS number 68083-19-2), between ten and thirty percent by weight hydrogen-terminated dimethyl siloxane (CAS 70900-21-9) and between 3 and 7 percent by weight trimethylated silica (CAS number 68909-20-6). In this embodiment, X may range between 30 and 90, Y may range between 2 and 20, and Z may range between 2 and 20, provided that X, Y and Z sum to 100 percent.

In some embodiments, the second material used to form the space 60 is a crystal clear silicon oil mixed with a dielectric gel. In some embodiments, the filler layer 330 has a volumetric thermal coefficient of expansion of greater than 250×10⁻⁶/° C., greater than 300×10⁻⁶/° C., greater than 400×10⁻⁶/° C., greater than 500×10⁻⁶/° C., greater than 1000×10⁻⁶/° C., greater than 2000×10⁻⁶/° C., greater than 5000×10⁻⁶/° C., or between 250×10⁻⁶/° C. and 10000×10⁻⁶/° C.

In some embodiments, a silicone-based dielectric gel can be used in-situ. The dielectric gel can also be mixed with a silicone based oil to reduce both beginning and ending viscosities. The ratio of silicone-based oil by weight in the mixture can be varied. The percentage of silicone-based oil by weight in the mixture of silicone-based oil and silicone-based dielectric gel can have values at or about (e.g. ±2.5%) 25%, 30%, 35%, 40%, 45%, 50%, 55%, 60%, 65%, 70%, 75%, and 85%. Ranges of 20%-30%, 25%-35%, 30%-40%, 35%-45%, 40%-50%, 45%-55%, 50%-60%, 55%-65%, 60%-70%, 65%-75%, 70%-80%, 75%-85%, and 80%-90% (by weight) are also contemplated. Further, these same ratios by weight can be contemplated for the mixture when using other types of oils or acrylates instead of or in addition to silicon-based oil to lessen the beginning viscosity of the gel mixture alone.

The initial viscosity of the mixture of 85% Dow Corning 200 fluid, 50 centistoke viscosity (PDMS, polydimethylsiloxane); 7.5% Dow Corning 3-4207 Dielectric Tough Gel, Part A—Resin 7.5% Dow Corning 3 4207 Dielectric Tough Gel, Part B—Pt Catalyst is approximately 100 centipoise (cP). Beginning viscosities of less than 1, less than 5, less than 10, less than 25, less than 50, less than 100, less than 250, less than 500, less than 750, less than 1000, less than 1200, less than 1500, less than 1800, and less than 2000 cP are imagined, and any beginning viscosity in the range 1-2000 cP is acceptable. Other ranges can include 1-10 cP, 10-50 cP, 50-100 cP, 100-250 cP, 250-500 cP, 500-750 cP, 750-1000 cP, 800-1200 cP, 1000-1500 cP, 1250-1750 cP, 1500-2000 cP, and 1800-2000 cP. In some cases an initial viscosity between 1000 cP and 1500 cP can also be used.

A final viscosity for the second material occupying the space 60 of well above the initial viscosity is envisioned in some embodiments. In most cases, a ratio of the final viscosity to the beginning viscosity is at least 50:1. With lower beginning viscosities, the ratio of the final viscosity to the beginning viscosity may be 20,000:1, or in some cases, up to 50,000:1. In most cases, a ratio of the final viscosity to the beginning viscosity of between 5,000:1 to 20,000:1, for beginning viscosities in the 10 cP range, may be used. For beginning viscosities in the 1000 cP range, ratios of the final viscosity to the beginning viscosity between 50:1 to 200:1 are imagined. In short order, ratios in the ranges of 200:1 to 1,000:1, 1,000:1 to 2,000:1, 2,000:1 to 5,000:1, 5,000:1 to 20,000:1, 20,000:1 to 50,000:1, 50,000:1 to 100,000:1, 100,000:1 to 150,000:1, and 150,000:1 to 200,000:1 are contemplated.

The final viscosity of the second material occupying space 60 is typically on the order of 50,000 cP to 200,000 cP. In some cases, a final viscosity of at least 1×10⁶ cP is envisioned. Final viscosities of at least 50,000 cP, at least 60,000 cP, at least 75,000 cP, at least 100,000 cP, at least 150,000 cP, at least 200,000 cP, at least 250,000 cP, at least 300,000 cP, at least 500,000 cP, at least 750,000 cP, at least 800,000 cP, at least 900,000 cP, and at least 1×10⁶ cP are all envisioned. Ranges of final viscosity for the filler layer 330 can include 50,000 cP to 75,000 cP, 60,000 cP to 100,000 cP, 75,000 cP to 150,000 cP, 100,000 cP to 200,000 cP, 100,000 cP to 250,000 cP, 150,000 cP to 300,000 cP, 200,000 cP to 500,000 cP, 250,000 cP to 600,000 cP, 300,000 cP to 750,000 cP, 500,000 cP to 800,000 cP, 600,000 cP to 900,000 cP, and 750,000 cP to 1×10⁶ cP.

Curing temperatures can be numerous, with a common curing temperature of room temperature. The curing step need not involve adding thermal energy to the system. Temperatures that can be used for curing can be envisioned (with temperatures in degrees F.) at up to 60 degrees, up to 65 degrees, up to 70 degrees, up to 75 degrees, up to 80 degrees, up to 85 degrees, up to 90 degrees, up to 95 degrees, up to 100 degrees, up to 105 degrees, up to 110 degrees, up to 115 degrees, up to 120 degrees, up to 125 degrees, and up to 130 degrees, and temperatures generally between 55 and 130 degrees. Other curing temperature ranges can include 60-85 degrees, 70-95 degrees, 80-110 degrees, 90-120 degrees, and 100-130 degrees.

The working time of the substance of a mixture can be varied as well. The working time of a mixture in this context means the time for the substance (e.g., the substance used to form the filler layer 330) to cure to a viscosity more than double the initial viscosity when mixed. Working time for the layer can be varied. In particular, working times of less than 5 minutes, on the order of 10 minutes, up to 30 minutes, up to 1 hour, up to 2 hours, up to 4 hours, up to 6 hours, up to 8 hours, up to 12 hours, up to 18 hours, and up to 24 hours are all contemplated. A working time of 1 day or less is found to be best in practice. Any working time between 5 minutes and 1 day is acceptable.

In the context of this disclosure, resin can mean both synthetic and natural substances that have a viscosity prior to curing and a greater viscosity after curing. The resin can be unitary in nature, or may be derived from the mixture of two other substances to form the resin.

In yet another embodiment the second material occupying space 60 may comprise solely a liquid. In one case the second material may be a dielectric oil. Such dielectric oils may be silicon-based. In one example, the oil can be 85% Dow Corning 200 fluid, 50 centistoke viscosity (PDMS, polydimethylsiloxane), One will realize that many differing oils can be used in place of polydimethylsiloxane, and this application should be read to include such other similar dielectric oils having the proper optical properties. Ranges of bulk viscosity of the oil by itself can range from include 0.1-1 centistokes, 1-5 centistokes, 5-10 centistokes, 10-25 centistokes, 25-50 centistokes, 40-60 centistokes, 50-75 centistokes, 75-100 centistokes, and 80-120 centistokes. Ranges between each of the individual points mentioned in this paragraph are also contemplated.

In some embodiments, the transparent casing 310, the optional filler layer 330, the optional antireflective layer 350, the water-resistant layer 340, or any combination thereof form a package to maximize and maintain the photovoltaic module 402 efficiency, provide physical support, and prolong the life time of photovoltaic modules 402.

In some embodiments, the second material occupying space 60 is a laminate layer such as any of those disclosed in U.S. Provisional patent application No. 60/906,901, filed Mar. 13, 2007, entitled “A Photovoltaic Apparatus Having a Laminate Layer and Method for Making the Same” which is hereby incorporated by reference herein in its entirety for such purpose. In some embodiments the second material occupying space 60 has a viscosity of less than 1×10⁶ cP. In some embodiments, second material has a thermal coefficient of expansion of greater than 500×10⁻⁶/° C. or greater than 1000×10⁻⁶/° C. In some embodiments, the second material comprises epolydimethylsiloxane polymer. In some embodiments, the second material comprises by weight: less than 50% of a dielectric gel or components to form a dielectric gel; and at least 30% of transparent silicon oil, the transparent silicon oil having a beginning viscosity of no more than half of the beginning viscosity of the dielectric gel or components to form the dielectric gel. In some embodiments, the second material has a thermal coefficient of expansion of greater than 500×10⁻⁶/° C. and comprises by weight: less than 50% of a dielectric gel or components to form a dielectric gel; and at least 30% of transparent silicon oil. In some embodiments, the second material is formed from silicon oil mixed with a dielectric gel. In some embodiments, the silicon oil is a polydimethylsiloxane polymer liquid and the dielectric gel is a mixture of a first silicone elastomer and a second silicone elastomer. In some embodiments, the filler layer 330 is formed from X %, by weight, polydimethylsiloxane polymer liquid, Y %, by weight, a first silicone elastomer, and Z %, by weight, a second silicone elastomer, where X, Y, and Z sum to 100. In some embodiments, the polydimethylsiloxane polymer liquid has the chemical formula (CH₃)₃SiO[SiO(CH₃)₂]ₙSi(CH₃)₃, where n is a range of integers chosen such that the polymer liquid has an average bulk viscosity that falls in the range between 50 centistokes and 100,000 centistokes. In some embodiments, first silicone elastomer comprises at least sixty percent, by weight, dimethylvinyl-terminated dimethyl siloxane and between 3 and 7 percent by weight silicate. In some embodiments, the second silicone elastomer comprises: (i) at least sixty percent, by weight, dimethylvinyl-terminated dimethyl siloxane; (ii) between ten and thirty percent by weight hydrogen-terminated dimethyl siloxane; and (iii) between 3 and 7 percent by weight trimethylated silica. In some embodiments, X is between 30 and 90; Y is between 2 and 20; and Z is between 2 and 20.

In some embodiments, the second material occupying space 60 comprises a silicone gel composition, comprising: (A) 100 parts by weight of a first polydiorganosiloxane containing an average of at least two silicon-bonded alkenyl groups per molecule and having a viscosity of from 0.2 to 10 Pa·s at 25° C.; (B) at least about 0.5 part by weight to about 10 parts by weight of a second polydiorganosiloxane containing an average of at least two silicon-bonded alkenyl groups per molecule, wherein the second polydiorganosiloxane has a viscosity at 25° C. of at least four times the viscosity of the first polydiorganosiloxane at 25° C.; (C) an organohydrogensiloxane having the average formula R₇Si(SiOR⁸₂H)₃ wherein R⁷ is an alkyl group having 1 to 18 carbon atoms or aryl, R⁸ is an alkyl group having 1 to 4 carbon atoms, in an amount sufficient to provide from 0.1 to 1.5 silicon-bonded hydrogen atoms per alkenyl group in components (A) and (B) combined; and (D) a hydrosilylation catalyst in an amount sufficient to cure the composition as disclosed in U.S. Pat. No. 6,169,155, which is hereby incorporated by reference herein.

All references cited herein are incorporated herein by reference in their entirety and for all purposes to the same extent as if each individual publication or patent or patent application was specifically and individually indicated to be incorporated by reference in its entirety for all purposes.

Accordingly, it should be clearly understood that the present invention is not intended to be limited by the particular features specifically described and illustrated in the drawings, but the concept of the present invention is to be measured by the scope of the appended claims. It should be understood that various changes, substitutions, and alterations could be made hereto without departing from the spirit and scope of the invention as described by the appended claims that follow.

We claim:

1. An apparatus for converting light energy to electric energy, the apparatus comprising:
(A) a first number of photovoltaic modules, each photovoltaic module in the first number of photovoltaic modules comprising:
(i) an outer shell defining an inner volume, the outer shell operable to allow light to enter the inner volume, the outer shell characterized by a longitudinal dimension and a cross-sectional dimension, the longitudinal dimension being greater than four times the cross-sectional dimension;
(ii) a substrate disposed within the inner volume;
(iii) a material disposed on a surface of the substrate and operable to convert light energy to electric energy; wherein
the outer shell is characterized by an optical property that directs a portion of light energy that strikes a surface of the outer shell towards the material;
(B) a concentrator comprising a first number of concentrator assemblies, each concentrator assembly in the first number of concentrator assemblies is associated with a corresponding photovoltaic module in the first number of photovoltaic modules, each respective concentrator assembly in the first number of concentrator assemblies comprising:
a first surface and a second surface that collectively form a concave structure operable to transmit light energy that enters the concave structure to the corresponding particular photovoltaic module;
the first surface and the second surface each comprising substantially a shape of the involute of the particular photovoltaic module corresponding to the respective concentrator assembly; and
the concave structure extending no more than a height of the particular photovoltaic module corresponding to the respective concentrator assembly; and
(C) a frame comprising:
a first support with a plurality of electric contacts disposed therein; and
a second support; wherein
each photovoltaic module in the first number of photovoltaic modules extends from the first support to the second support;
each photovoltaic module in the first number of photovoltaic modules is electrically coupled to an electric contact in the plurality of electric contacts disposed within the first support; and wherein
the concentrator is mechanically attached to the frame.

2. An apparatus for converting light energy to electric energy, the apparatus comprising:
(A) an outer shell defining an inner volume, the outer shell operable to allow light to enter the inner volume, the outer shell characterized by a longitudinal dimension and a cross-sectional dimension, the longitudinal dimension being greater than four times the cross-sectional dimension;
(B) a substrate disposed within the inner volume;
(C) a material disposed on a surface of the substrate and operable to convert light energy to electric energy, wherein the outer shell is characterized by an optical property that directs a portion of the light energy striking a surface of the outer shell towards the substrate; and
(D) a concentrator assembly comprising a first surface and a second surface that collectively form a concave structure operable to transmit light energy that enters the concave structure to the outer shell, the concave structure extending no more than a height of the outer shell.

3. A method of converting light energy emanating from a light source into electric energy, the method comprising:
(A) providing a concave member with an opening generally facing the light source and defining an inner receiving volume, the concave member comprising a pair of walls with upper edges that collectively define a plane normal to a first component of the light energy emanating from the light source, wherein a distance between the pair of walls is a first width;
(B) providing a photovoltaic module disposed at least partially within the inner receiving volume, a length of the photovoltaic module being at least four times a width of the photovoltaic module, the width of the photovoltaic module being at least one-third the first width, the photovoltaic module comprising:
(a) an outer assembly comprising an outer wall that defines (i) a module width and (ii) an inner volume;
(b) an inner assembly disposed within the inner volume, the inner assembly comprising a substrate and a first material disposed on the substrate, the first material operable to generate electric energy from (i) light with a component parallel to the first component and (ii) light with a component anti-parallel to the first component;
with the concave member, receiving light energy emanating from the light source, the concave member redirecting a portion of the light energy received from the light source onto the photovoltaic module as redirected light; and
(C) with the photovoltaic module:
(i) receiving light energy directly from the light source and directing that light energy onto the first material, wherein at least a portion of the light energy received directly from the light source has a component that is parallel to said first component; and
(ii) receiving said redirected light from the concave member and directing the redirected light onto the first material, wherein at least a portion of the redirected light has a component anti-parallel to the first component.

4. An assembly for converting light energy to electric energy, the assembly comprising:
(A) an outer shell defining an inner volume, the outer shell operable to allow light to enter the inner volume, wherein the outer shell is characterized by a longitudinal dimension and a cross-sectional dimension, the longitudinal dimension being greater than four times the cross-sectional dimension;
(B) a substrate disposed within the inner volume, the outer shell and the substrate defining an annular volume between them;
(C) a first material disposed on the substrate operable to convert light energy to electric energy;
(D) a second material disposed in the annular volume, wherein the outer shell has an optical property of redirecting a portion of light energy that strikes a surface of the outer shell towards the second material and wherein the second material is operable to redirect light from the outer shell to the first material; and
(E) a concentrator assembly comprising a first surface and a second surface that collectively form a concave structure operable to transmit light energy that enters the concave structure to the outer shell, wherein the concave structure extends no more than a height of the outer shell.

5. An assembly for converting light energy to electric energy, the assembly comprising:
(A) an outer shell defining an inner volume, the outer shell operable to allow light to enter the inner volume, the outer shell characterized by a longitudinal dimension and a cross-sectional dimension, the longitudinal dimension being greater than four times the cross-sectional dimension;
(B) a substrate disposed within the inner volume, the outer shell and the substrate defining an annular volume between them;
(C) a first material disposed on a surface of the substrate operable to convert light energy to electric energy, wherein the first material has an index of refraction that is greater than that of air;
(D) a second material disposed in the annular volume, wherein the second material has an index of refraction equal to or less than that of the first material; and
(E) a concentrator comprising a first surface and a second surface that collectively form a concave structure operable to transmit light energy that enters the concave structure to the outer shell.

6. An apparatus for converting light energy to electric energy, the apparatus comprising:
(A) a plurality of photovoltaic modules, each photovoltaic module in the plurality of photovoltaic modules comprising:
(i) an outer shell defining an inner volume, the outer shell operable to allow light to enter the inner volume;
(ii) a substrate disposed within the inner volume;
(iii) one or more solar cells disposed on all or a portion of a surface of the substrate, wherein each solar cell in the one or more solar cells is operable to convert light energy to electric energy; wherein
the outer shell is characterized by an optical property that causes at least a portion of the light energy that strikes a surface of the outer shell to be directed towards the one or more solar cells on the substrate; and
(B) a concentrator comprising a plurality of concentrator assemblies, wherein each respective concentrator assembly in the plurality of concentrator assemblies is associated with a corresponding photovoltaic module in the plurality of photovoltaic modules, and wherein each respective concentrator assembly in the plurality of concentrator assemblies comprises:
a first surface and a second surface that collectively form a concave structure operable to transmit light energy that enters the concave structure to the corresponding photovoltaic module in the plurality of photovoltaic modules; wherein
at least a portion of the first surface and at least a portion of the second surface each comprise substantially the shape of an involute of the particular photovoltaic module associated with the respective concentrator assembly.

7. The apparatus of claim 6, wherein the outer shell is characterized by a longitudinal dimension and a cross-sectional dimension, and wherein the longitudinal dimension is greater than four times the cross-sectional dimension.

8. The apparatus of claim 6, wherein the first surface and the second surface of a concentrator assembly in the plurality of concentrator assemblies extends no more than the height of the corresponding photovoltaic module associated with the concentrator assembly.

9. The apparatus of claim 6, the apparatus further comprising:
(C) a frame comprising:
a first support with a plurality of electric contacts disposed therein; and
a second support; wherein
each photovoltaic module in the plurality of photovoltaic modules extends from the first support to the second support;
each photovoltaic module in the plurality of photovoltaic modules is electrically coupled to an electric contact in the plurality of electric contacts disposed within the first support; and wherein
the concentrator is mechanically attached to the frame.

10. An apparatus for converting light energy to electric energy, the apparatus comprising:
(A) an outer shell defining an inner volume, the outer shell operable to allow light to enter the inner volume;
(B) a substrate disposed within the inner volume;
(C) one or more solar cells disposed on a surface of the substrate; wherein each solar cell in the one or more solar cells is operable to convert light energy to electric energy, wherein the outer shell is characterized by an optical property that directs a portion of light energy that strikes a surface of the outer shell towards the one or more solar cells; and
(D) a concentrator assembly comprising a first surface and a second surface that collectively form a concave structure operable to transmit light energy that enters the concave structure to the outer shell.

11. The apparatus of claim 10, wherein the outer shell is characterized by a longitudinal dimension and a cross-sectional dimension, wherein the longitudinal dimension is greater than four times the cross-sectional dimension.

12. The apparatus of claim 10, wherein the first surface and the second surface extend no more than the height of the outer shell.

13. A method of converting light energy emanating from a light source into electric energy, the method comprising:
providing a concave member with an opening generally facing the light source and defining an inner receiving volume, the concave member comprising two lateral walls with upper edges that define a plane normal to a first component of light energy emanating directly from the light source, wherein a distance between the two lateral walls is a first width;
providing a photovoltaic module disposed at least partially within the inner receiving volume, the photovoltaic module comprising:
(a) an outer assembly having an outer wall defining a module width and an inner volume;
(b) an inner assembly disposed within the inner volume, the inner assembly comprising a substrate and one or more solar cells disposed on a surface of the substrate, the one or more solar cells operable to convert light energy into electric energy;
wherein the one or more solar cells are operable to generate electric energy from light having a component parallel to the first component and from light having a component anti-parallel to the first component;
with the concave member, receiving incoming light energy from the source, the concave member redirecting a portion of the light energy onto the photovoltaic module;
with the photovoltaic module:
(i) receiving direct light energy from the light source and directing that light energy onto the one or more solar cells;
(ii) receiving light energy redirected from the concentrator and directing that redirected light energy onto the one or more solar cells, wherein at least a portion of the redirected light energy striking the photovoltaic module has a component anti-parallel to the first component.

14. The method of claim 13, wherein the photovoltaic module has a length at least four times its width, the width of the photovoltaic module being at least one-third the width of the first width.

15. An assembly for converting light energy to electric energy, the assembly comprising:
(A) an outer shell defining an inner volume, the outer shell operable to allow light to enter the inner volume;
(B) a substrate disposed within the inner volume, the outer shell and the substrate defining an annular volume between them;
(C) one or more solar cells disposed on a surface of the substrate, the one or more solar cells operable to convert light energy to electric energy;
(D) a material disposed in the annular volume; wherein the outer shell has an optical property that redirects a portion of the light energy that strikes a surface of the outer shell towards the material and wherein the material is operable to redirect light from the outer shell to the one or more solar cells; and
(E) a concentrator assembly comprising a first surface and a second surface that collectively form a concave structure operable to transmit light energy that enters the concave structure to the outer shell.

16. The assembly of claim 15, wherein the outer shell is characterized by a longitudinal dimension and a cross-sectional dimension, the longitudinal dimension being greater than four times the cross-sectional dimension.

17. The assembly of claim 15, wherein the first surface and the second surface extend no more than a height of the outer shell.

18. An assembly for converting light energy to electric energy, the assembly comprising:
(A) an outer shell defining an inner volume, the outer shell operable to allow light to enter the inner volume;
(B) a substrate disposed within the inner volume, the outer shell and the substrate defining an annular volume between them;
(C) one or more solar cells disposed on all or a portion of a surface of the substrate, wherein the one or more solar cells are each operable to convert light energy to electric energy and wherein an upper layer of a solar cell in the one or more solar cells has an index of refraction greater than that of air;
(D) a material disposed in the annular volume having an index of refraction equal to or less than that of said upper layer of said solar cell; and
(E) a concentrator assembly comprising a first surface and a second surface that collectively form a concave structure operable to transmit light energy that enters the concave structure to the outer shell.

19. The assembly of claim 18, wherein the outer shell is characterized by having a longitudinal dimension and a cross-sectional dimension, the longitudinal dimension being greater than four times the cross-sectional dimension.

20. The apparatus of claim 6, wherein the substrate of a photovoltaic module in the plurality of photovoltaic modules is nonplanar.

21. The apparatus of claim 6, wherein the substrate of a photovoltaic module in the plurality of photovoltaic modules is cylindrical or substantially cylindrical.

22. The apparatus of claim 6, wherein a solar cell in the one or more solar cells comprises:
(i) a conducting material disposed on the substrate;
(ii) a semiconductor junction disposed on the conducting material; and
(iii) a transparent conducting material disposed on the semiconductor junction.

23. The apparatus of claim 22, wherein the conducting material comprises aluminum, molybdenum, tungsten, vanadium, rhodium, niobium, chromium, tantalum, titanium, steel, nickel, platinum, silver, gold, an alloy thereof, or any combination thereof.

24. The apparatus of claim 22, wherein the conducting material comprises indium tin oxide, titanium nitride, tin oxide, fluorine doped tin oxide, doped zinc oxide, aluminum doped zinc oxide, gallium doped zinc oxide, boron doped zinc oxide indium-zinc oxide, a metal-carbon black-filled oxide, a graphite-carbon black filled oxide, a carbon black carbon black-filled oxide, a superconductive carbon black-filled oxide, an epoxy, a conductive glass, or a conductive plastic.

25. The apparatus of claim 22, wherein the semiconductor junction comprises a homojunction, a heterojunction, a heteroface junction, a buried homojunction, a p-i-n junction, or a tandem junction.

26. The apparatus of claim 22, wherein the transparent conductive layer comprises carbon nanotubes, tin oxide, fluorine doped tin oxide, indium-tin oxide (ITO), doped zinc oxide, aluminum doped zinc oxide, gallium doped zinc oxide, boron doped zinc oxide indium-zinc oxide or any combination thereof or any combination thereof.

27. The apparatus of claim 22, wherein the semiconductor junction comprises an absorber layer and a junction partner layer, wherein said junction partner layer is disposed on said absorber layer.

28. The apparatus of claim 27, wherein the absorber layer comprises copper-indium-gallium-diselenide and said junction partner layer comprises In₂Se₃, In₂S₃, ZnS, ZnSe, CdlnS, CdZnS, ZnIn₂Se₄, Zn₁₋ₓMgₓO, CdS, SnO₂, ZnO, ZrO₂, or doped ZnO.

29. The apparatus of claim 27, wherein the absorber layer comprises copper-indium-gallium-diselenide and said junction partner layer comprises CdS.

30. The apparatus of claim 22, further comprising:
a filler layer that is circumferentially disposed onto the transparent conductive layer; and
the outer shell is circumferentially disposed on said filler layer.

31. The apparatus of claim 30, wherein the filler layer has a viscosity of less than 1×10₆ cP.

32. The apparatus of claim 6, wherein the substrate and/or the outer shell of a photovoltaic module in the plurality of photovoltaic modules is characterized by a circular cross-section, an ovoid cross-section, a triangular cross-section, a pentangular cross-section, a hexagonal cross-section, a cross-section having at least one arcuate portion, or a cross-section having at least one curved portion.

33. The apparatus of claim 6, wherein a substrate of a photovoltaic module in the plurality of photovoltaic modules is made of a rigid material.

34. The apparatus of claim 33, wherein the rigid material has a Young's modulus of 20 GPa or greater.

35. The apparatus of claim 33, wherein the rigid material has a Young's modulus of 50 GPa or greater.

36. The apparatus of claim 10, wherein the substrate is nonplanar.

37. The apparatus of claim 10, wherein the substrate is cylindrical or substantially cylindrical.

38. The apparatus of claim 10, wherein a solar cell in the one or more solar cells comprises:
(i) a conducting material disposed on the substrate;
(ii) a semiconductor junction disposed on the conducting material; and
(iii) a transparent conducting material disposed on the semiconductor junction.

39. The apparatus of claim 38, wherein the conducting material disposed on the substrate comprises aluminum, molybdenum, tungsten, vanadium, rhodium, niobium, chromium, tantalum, titanium, steel, nickel, platinum, silver, gold, an alloy thereof, or any combination thereof.

40. The apparatus of claim 38, wherein the conducting material disposed on the substrate comprises indium tin oxide, titanium nitride, tin oxide, fluorine doped tin oxide, doped zinc oxide, aluminum doped zinc oxide, gallium doped zinc oxide, boron doped zinc oxide indium-zinc oxide, a metal-carbon black-filled oxide, a graphite-carbon black filled oxide, a carbon black carbon black-filled oxide, a superconductive carbon black-filled oxide, an epoxy, a conductive glass, or a conductive plastic.

41. The apparatus of claim 38, wherein the semiconductor junction comprises a homojunction, a heterojunction, a heteroface junction, a buried homojunction, a p-i-n junction, or a tandem junction.

42. The apparatus of claim 38, wherein the transparent conductive layer comprises carbon nanotubes, tin oxide, fluorine doped tin oxide, indium-tin oxide (ITO), doped zinc oxide, aluminum doped zinc oxide, gallium doped zinc oxide, boron doped zinc oxide indium-zinc oxide or any combination thereof or any combination thereof.

43. The apparatus of claim 38, wherein the semiconductor junction comprises an absorber layer and a junction partner layer, wherein said junction partner layer is disposed on said absorber layer.

44. The apparatus of claim 43, wherein the absorber layer comprises copper-indium-gallium-diselenide and said junction partner layer comprises In₂Se₃, In₂S₃, ZnS, ZnSe, CdlnS, CdZnS, ZnIn₂Se₄, Zn₁₋ₓMgₓO, CdS, SnO₂, ZnO, ZrO₂, or doped ZnO.

45. The apparatus of claim 38, the apparatus further comprising:
a filler layer that is circumferentially disposed onto the transparent conductive layer; and
the outer shell is circumferentially disposed on said filler layer.

46. The apparatus of claim 45, wherein the filler layer is a liquid with a viscosity of less than 1×10₆ cP.

47. The apparatus of claim 45, wherein the filler layer has an index of refraction that is (i) less than an index of refraction of the transparent conducting layer and (ii) greater than an index of refraction of the outer shell.

48. The apparatus of claim 10, wherein the substrate and/or the outer shell is characterized by a circular cross-section, an ovoid cross-section, a triangular cross-section, a pentangular cross-section, a hexagonal cross-section, a cross-section having at least one arcuate portion, or a cross-section having at least one curved portion.

49. The apparatus of claim 10, wherein a substrate of a photovoltaic module in the plurality of photovoltaic modules is made of a rigid material.

50. The apparatus of claim 49, wherein the rigid material has a Young's modulus of 20 GPa or greater.

51. The apparatus of claim 49, wherein the rigid material has a Young's modulus of 50 GPa or greater.

52. The method of claim 13, wherein the substrate is nonplanar.

53. The method of claim 13, wherein the substrate is cylindrical or substantially cylindrical.

54. The method of claim 13, wherein a solar cell in the one or more solar cells comprises:
(i) a conducting material disposed on the substrate;
(ii) a semiconductor junction disposed on the conducting material; and
(iii) a transparent conducting material disposed on the semiconductor junction.

55. The method of claim 54, wherein the conducting material disposed on the substrate comprises aluminum, molybdenum, tungsten, vanadium, rhodium, niobium, chromium, tantalum, titanium, steel, nickel, platinum, silver, gold, an alloy thereof, or any combination thereof.

56. The method of claim 54, wherein the conducting material disposed on the substrate comprises indium tin oxide, titanium nitride, tin oxide, fluorine doped tin oxide, doped zinc oxide, aluminum doped zinc oxide, gallium doped zinc oxide, boron doped zinc oxide indium-zinc oxide, a metal-carbon black-filled oxide, a graphite-carbon black filled oxide, a carbon black carbon black-filled oxide, a superconductive carbon black-filled oxide, an epoxy, a conductive glass, or a conductive plastic.

57. The method of claim 54, wherein the semiconductor junction comprises a homojunction, a heterojunction, a heteroface junction, a buried homojunction, a p-i-n junction, or a tandem junction.

58. The method of claim 54, wherein the semiconductor junction comprises an absorber layer and a junction partner layer, wherein said junction partner layer is disposed on said absorber layer.

59. The method of claim 54, wherein the absorber layer comprises copper-indium-gallium-diselenide and said junction partner layer comprises In₂Se₃, In₂S₃, ZnS, ZnSe, CdlnS, CdZnS, ZnIn₂Se₄, Zn₁₋ₓMgₓO, CdS, SnO₂, ZnO, ZrO₂, or doped ZnO.

60. The method of claim 54, wherein:
a filler layer is circumferentially disposed onto the transparent conductive layer; and
the outer assembly is circumferentially disposed on said filler layer.

61. The method of claim 60, wherein the filler layer is a liquid with a viscosity of less than 1×10₆ cP.

62. The method of claim 60, wherein the filler layer has an index of refraction that is (i) less than an index of refraction of the transparent conducting layer and (ii) greater than an index of refraction of the outer assembly.

63. The method of claim 13, wherein the substrate and/or the outer assembly is characterized by a circular cross-section, an ovoid cross-section, a triangular cross-section, a pentangular cross-section, a hexagonal cross-section, a cross-section having at least one arcuate portion, or a cross-section having at least one curved portion.

64. The method of claim 13, wherein the substrate is made of a rigid material.

65. The method of claim 64, wherein the rigid material has a Young's modulus of 20 GPa or greater.

66. The method of claim 64, wherein the rigid material has a Young's modulus of 50 GPa or greater.

67. The apparatus of claim 15, wherein the substrate is nonplanar.

68. The apparatus of claim 15, wherein the substrate is cylindrical or substantially cylindrical.

69. The apparatus of claim 15, wherein a solar cell in the one or more solar cells comprises:
(i) a conducting material disposed on the substrate;
(ii) a semiconductor junction disposed on the conducting material; and
(iii) a transparent conducting material disposed on the semiconductor junction.

70. The apparatus of claim 69, wherein the conducting material disposed on the substrate comprises aluminum, molybdenum, tungsten, vanadium, rhodium, niobium, chromium, tantalum, titanium, steel, nickel, platinum, silver, gold, an alloy thereof, or any combination thereof.

71. The apparatus of claim 69, wherein the conducting material disposed on the substrate comprises indium tin oxide, titanium nitride, tin oxide, fluorine doped tin oxide, doped zinc oxide, aluminum doped zinc oxide, gallium doped zinc oxide, boron doped zinc oxide indium-zinc oxide, a metal-carbon black-filled oxide, a graphite-carbon black filled oxide, a carbon black carbon black-filled oxide, a superconductive carbon black-filled oxide, an epoxy, a conductive glass, or a conductive plastic.

72. The apparatus of claim 69, wherein the semiconductor junction comprises a homojunction, a heterojunction, a heteroface junction, a buried homojunction, a p-i-n junction, or a tandem junction.

73. The apparatus of claim 69, wherein the transparent conductive layer comprises carbon nanotubes, tin oxide, fluorine doped tin oxide, indium-tin oxide (ITO), doped zinc oxide, aluminum doped zinc oxide, gallium doped zinc oxide, boron doped zinc oxide indium-zinc oxide or any combination thereof or any combination thereof.

74. The apparatus of claim 69, wherein the semiconductor junction comprises an absorber layer and a junction partner layer, wherein said junction partner layer is disposed on said absorber layer.

75. The apparatus of claim 74, wherein the absorber layer comprises copper-indium-gallium-diselenide and said junction partner layer comprises In₂Se₃, In₂S₃, ZnS, ZnSe, CdlnS, CdZnS, ZnIn₂Se₄, Zn₁₋ₓMgₓO, CdS, SnO₂, ZnO, ZrO₂, or doped ZnO.

76. The apparatus of claim 69, wherein:
a filler layer is circumferentially disposed onto the transparent conductive layer; and
the outer shell is circumferentially disposed on said filler layer.

77. The apparatus of claim 76, wherein the filler layer is a liquid with a viscosity of less than 1×10₆ cP.

78. The apparatus of claim 76, wherein the filler layer has an index of refraction that is (i) less than an index of refraction of the transparent conducting layer and (ii) greater than an index of refraction of the outer assembly.

79. The apparatus of claim 15, wherein the substrate and/or the outer shell is characterized by a circular cross-section, an ovoid cross-section, a triangular cross-section, a pentangular cross-section, a hexagonal cross-section, a cross-section having at least one arcuate portion, or a cross-section having at least one curved portion.

80. The apparatus of claim 15, wherein the substrate is made of a rigid material.

81. The apparatus of claim 80, wherein the rigid material has a Young's modulus of 20 GPa or greater.

82. The apparatus of claim 80, wherein the rigid material has a Young's modulus of 50 GPa or greater.

83. The apparatus of claim 18, wherein the substrate is nonplanar.

84. The apparatus of claim 18, wherein the substrate is cylindrical or substantially cylindrical.

85. The apparatus of claim 18, wherein a solar cell in the one or more solar cells comprises:
(i) a conducting material disposed on the substrate;
(ii) a semiconductor junction disposed on the conducting material; and
(iii) a transparent conducting material disposed on the semiconductor junction.

86. The apparatus of claim 85, wherein the conducting material disposed on the substrate comprises aluminum, molybdenum, tungsten, vanadium, rhodium, niobium, chromium, tantalum, titanium, steel, nickel, platinum, silver, gold, an alloy thereof, or any combination thereof.

87. The apparatus of claim 85, wherein the conducting material disposed on the substrate comprises indium tin oxide, titanium nitride, tin oxide, fluorine doped tin oxide, doped zinc oxide, aluminum doped zinc oxide, gallium doped zinc oxide, boron doped zinc oxide indium-zinc oxide, a metal-carbon black-filled oxide, a graphite-carbon black filled oxide, a carbon black carbon black-filled oxide, a superconductive carbon black-filled oxide, an epoxy, a conductive glass, or a conductive plastic.

88. The apparatus of claim 85, wherein the semiconductor junction comprises a homojunction, a heterojunction, a heteroface junction, a buried homojunction, a p-i-n junction, or a tandem junction.

89. The apparatus of claim 85, wherein the transparent conductive layer comprises carbon nanotubes, tin oxide, fluorine doped tin oxide, indium-tin oxide (ITO), doped zinc oxide, aluminum doped zinc oxide, gallium doped zinc oxide, boron doped zinc oxide indium-zinc oxide or any combination thereof or any combination thereof.

90. The apparatus of claim 85, wherein the semiconductor junction comprises an absorber layer and a junction partner layer, wherein said junction partner layer is disposed on said absorber layer.

91. The apparatus of claim 90, wherein the absorber layer comprises copper-indium-gallium-diselenide and said junction partner layer comprises In₂Se₃, In₂S₃, ZnS, ZnSe, CdlnS, CdZnS, ZnIn₂Se₄, Zn₁₋ₓMgₓO, CdS, SnO₂, ZnO, ZrO₂, or doped ZnO.

92. The apparatus of claim 85, wherein:
a filler layer is circumferentially disposed onto the transparent conductive layer; and
the outer shell is circumferentially disposed on said filler layer.

93. The apparatus of claim 92, wherein the filler layer is a liquid with a viscosity of less than 1×10₆ cP.

94. The apparatus of claim 91, wherein the filler layer has an index of refraction that is (i) less than an index of refraction of the transparent conducting layer and (ii) greater than an index of refraction of the outer assembly.

95. The apparatus of claim 18, wherein the substrate and/or the outer shell is characterized by a circular cross-section, an ovoid cross-section, a triangular cross-section, a pentangular cross-section, a hexagonal cross-section, a cross-section having at least one arcuate portion, or a cross-section having at least one curved portion.

96. The apparatus of claim 18, wherein the substrate is made of a rigid material.

97. The apparatus of claim 96, wherein the rigid material has a Young's modulus of 20 GPa or greater.

98. The apparatus of claim 96, wherein the rigid material has a Young's modulus of 50 GPa or greater.
